(19) United States
(12) Patent Application Publication
(10) Pub. No.: US 2023/0317175 A1
(43) Pub. Date: Oct. 5, 2023

(54) SEMICONDUCTOR DEVICE, FIRMWARE WRITING METHOD, AND FIRMWARE WRITING SYSTEM

(71) Applicant: LAPIS TECHNOLOGY CO., LTD., YOKOHAMA (JP)

(72) Inventor: EIKICHI SHIMIZU, YOKOHAMA (JP)

(21) Appl. No.: 18/128,380

(22) Filed: Mar. 30, 2023

(30) Foreign Application Priority Data
Mar. 31, 2022 (JP) 2022-059290

(51) Int. Cl. G11C 16/26; G11C 16/10

(52) U.S. Cl. CPC G11C 16/26; G11C 16/10

(57) ABSTRACT

Provided is a semiconductor device that allows speeding up write speed while reducing an increase in circuit size. The semiconductor device includes a processing control unit, a memory unit, an ordinary interface unit, and a high-speed interface unit. The processing control unit executes a predetermined operation. The ordinary interface unit transfers input data to the memory unit. The high-speed interface unit operates by executing high-speed write firmware by the processing control unit to transfer input data to the memory unit at a higher speed than the ordinary interface unit.

### BACKGROUND

### 1. Technical Field

The present invention relates to a semiconductor device, a firmware writing method to a semiconductor device, and a firmware writing system.

### 2. Description of the Related Art

To a non-volatile memory disposed in a semiconductor device, firmware (FW) is written from outside the semiconductor device. Such firmware write is generally performed via a serial communication interface (for example, JP-A-2006-279706).

### SUMMARY

Like the above-described related art, when FW write is performed directly to a non-volatile memory via a serial interface from outside, there has been a problem in that a write speed is slow. Therefore, without writing FW directly into a non-volatile memory, FW is written by storing the FW once in a volatile memory with fast access speed via a serial interface, such as a debugger interface, and later transferring it to a non-volatile memory. However, since the debugger interface is also a serial interface, there has been a problem in that it takes time to store FW in the volatile memory.

Additionally, in order to speed up the write speed, it is considered to write using hardware that allows writing in parallel, instead of writing via a serial interface. However, there has been a problem in that a circuit size increases when hardware dedicated to performing a high-speed write is disposed.

The present invention has been made in consideration of the problems, and an object of the present invention is to provide a semiconductor device, a firmware writing method, and a firmware writing system that allow speeding up write speed while reducing an increase in circuit size.

The semiconductor device according to the present invention includes a processing control unit that executes a predetermined operation, a memory unit, an ordinary interface unit that transfers input data to the memory unit, and a high-speed interface unit that operates by executing high-speed write firmware by the processing control unit to transfer input data to the memory unit at a higher speed than the ordinary interface unit.

The firmware writing method according to the present invention is a firmware writing method for writing ordinary firmware for executing a predetermined operation into a memory unit in a semiconductor device, wherein the semiconductor device includes a processing control unit that executes the predetermined operation, the memory unit, an ordinary interface unit that transfers input data to the memory unit, and a high-speed interface unit that transfers input data to the memory unit at a higher speed than the ordinary interface unit, and the firmware writing method comprises executing high-speed write firmware for controlling the high-speed interface unit by the processing control unit to write the ordinary firmware into the memory unit via the high-speed interface unit.

The firmware writing system according to the present invention includes a semiconductor device including a processing control unit that executes a predetermined operation, a memory unit, an ordinary interface unit that transfers input data to the memory unit, and a high-speed interface unit that transfers input data to the memory unit at a higher speed than the ordinary interface unit; and a writing device, wherein high-speed write firmware for controlling the high-speed interface unit is written into the memory unit, the writing device supplies ordinary firmware for executing the predetermined operation to the high-speed interface unit, and the processing control unit writes the ordinary firmware into the memory unit via the high-speed interface unit by reading the high-speed write firmware from the memory unit and executing the high-speed write firmware.

The semiconductor device according to the present invention allows speeding up write speed while reducing an increase in circuit size.

### BRIEF DESCRIPTION OF THE DRAWINGS

Features of the present invention will be described below with reference to the accompanying drawings.

FIG. 1 is a block diagram illustrating a configuration of a firmware writing system of Embodiment 1;

FIG. 2 is a flowchart illustrating a process routine of a firmware writing process of Embodiment 1;

FIG. 3 is a diagram schematically illustrating a processing operation of the firmware writing process of Embodiment 1;

FIG. 4 is a flowchart illustrating a process routine of a firmware writing process of Embodiment 2;

FIG. 5 is a diagram schematically illustrating a processing operation of the firmware writing process of Embodiment 2;

FIG. 6 is a block diagram illustrating a configuration of a firmware writing system of Embodiment 3;

FIG. 7 is a flowchart illustrating a process routine of a firmware writing process of Embodiment 3; and

FIG. 8 is a diagram schematically illustrating a processing operation of the firmware writing process of Embodiment 3.

### DETAILED DESCRIPTION

The following describes embodiments of the present invention with reference to the drawings. Note that the same reference numerals are given to substantially identical or equivalent parts in the description in the following respective embodiments and the accompanying drawings.

### Embodiment 1

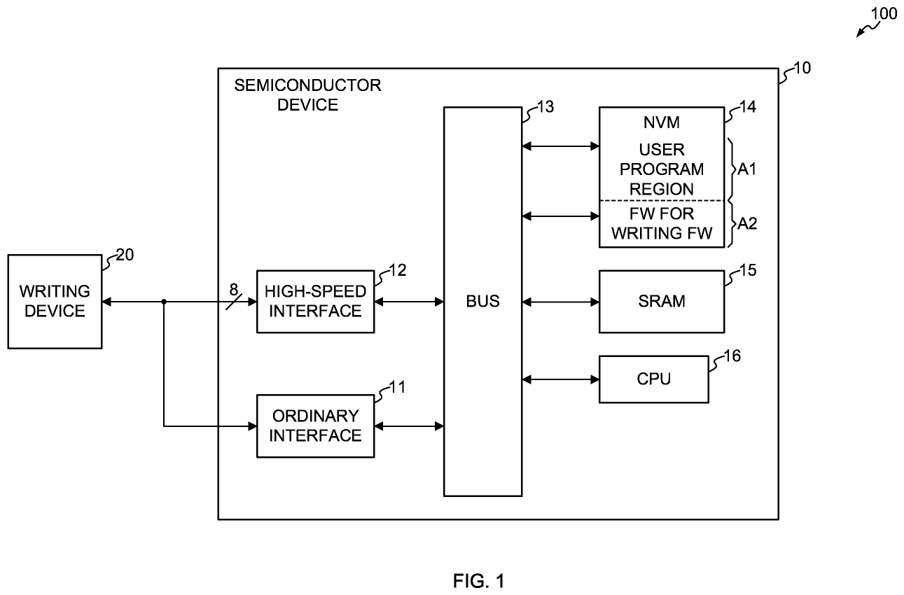

FIG. 1 is a block diagram illustrating a configuration of a firmware writing system 100 according to Embodiment 1 of the present invention. The firmware writing system 100 is constituted of a semiconductor device 10 and a writing device 20.

The semiconductor device 10 is constituted of a Large Scale Integration (LSI) having memories. The writing device 20 is disposed outside the semiconductor device 10. The writing device 20 is a device that writes firmware for causing a processing control unit of the semiconductor device 10 to execute a predetermined operation into the semiconductor device 10. Firmware is held in a memory of the semiconductor device 10. The firmware is updated in response to the write by the writing device 20.

For example, the semiconductor device 10 is a device built in an embedded device, such as a home appliance, a vending machine, and a car navigation device inside an automobile, to control the operation of the devices. In other words, the semiconductor device 10 is a device that realizes an embedded system.

The semiconductor device 10 includes an ordinary interface 11, a high-speed interface 12, a bus 13, an NVM 14, an SRAM 15, and a CPU 16. The NVM 14 and the SRAM 15 are examples of memory units of the semiconductor device 10.

The ordinary interface 11 is an interface that performs ordinary serial communication or parallel communication and is an example of an ordinary interface unit. The ordinary interface 11 is, for example, an interface for debugging the semiconductor device 10. In this embodiment, the ordinary interface 11 is, for example, a Serial Peripheral Interface (SPI) for serial communication and is configured to allow transferring 1-bit data during one clock cycle via one data line. The ordinary interface 11 may be a serial port compliant with a standard, such as RS-232. In other words, the ordinary interface 11 is an interface that hardly requires software support.

The high-speed interface 12 is an interface that performs serial communication or parallel communication at a higher speed than the ordinary interface 11 and is an example of a high-speed interface unit. The high-speed interface 12 is, for example, configured to allow transferring plural-bit data during one clock cycle via a plurality of data lines. Moreover, the high-speed interface 12 is configured to allow transferring data at a second speed faster than a first speed when the ordinary interface 11 transfers data to one data line at the first speed. In this embodiment, the high-speed interface 12 is, for example, an Octal Serial Peripheral Interface (OSPI) and is configured to allow transferring 8-bit (1-byte) data during one clock cycle via eight data lines. Here, the phrase “higher speed than the ordinary interface 11” includes having more data lines than the ordinary interface 11 or having a faster speed for transferring data per data line than the ordinary interface 11.

Unlike the ordinary interface 11, the high-speed interface 12 is an interface that requires software support for data transferring. The high-speed interface 12 transfers data in response to a command from the CPU 16 that executes the software for data transferring. For example, in this embodiment, the high-speed interface 12 is supplied with data from the writing device 20 and latches the data. Then, the high-speed interface 12 transfers the latched data to the NVM 14 in response to a command from the CPU 16.

The bus 13 is an internal bus disposed inside the semiconductor device 10. Respective units in the semiconductor device 10 are accessed via the bus 13.

The NVM 14 is an example of a non-volatile memory built in the semiconductor device 10. In the NVM 14, a user program region A1 as a first region and a firmware region A2 as a second region are disposed. The user program region A1 is a region into which firmware as a user program for running the semiconductor device 10 is allowed to be written in a memory area. The firmware region A2 is a region into which firmware for writing used for writing the firmware is written.

In the following description, the firmware written into the NVM 14 as a user program is referred to as “ordinary FW.” The firmware for writing used for writing the ordinary FW is referred to as “FW-writing FW.” The ordinary FW is ordinary firmware for the CPU 16 to execute a predetermined operation. The FW-writing FW is data-transferring firmware to support data transferring by the high-speed interface 12. In other words, the FW-writing FW is high-speed write firmware used for the CPU 16 to control the high-speed interface 12 to execute a high-speed write of the ordinary FW.

In this embodiment, the FW-writing FW is preliminarily written into the firmware region A2 of the NVM 14 in, for example, a shipping inspection process or the like of the LSI constituting the semiconductor device 10. That is, in this embodiment, a writing process of the ordinary FW described later is started in a state where the FW-writing FW has been preliminarily written in the NVM 14. The preliminary write of the FW-writing FW into the NVM 14 is performed, for example, from the writing device 20, which is a device disposed outside the semiconductor device 10, via the ordinary interface 11.

The FW-writing FW is extremely small in data size compared with the ordinary FW. For example, when the size of the ordinary FW is 2 MB, the size of the FW-writing FW is around 4 KB. In view of this, the preliminary write of the FW-writing FW can be performed in an extremely short period compared with the write of the ordinary FW.

The Static Random Access Memory (SRAM) 15 is an example of a volatile memory built in the semiconductor device 10. The SRAM 15 is used as a work area for temporarily storing data when the CPU 16 performs a processing operation.

The Central Processing Unit (CPU) 16 is a processing control unit that controls operations of respective units of the semiconductor device 10. The CPU 16 also controls a write to or read from the NVM 14. In this embodiment, the CPU 16 controls the read of the FW-writing FW from the NVM 14 and the data write to the NVM 14 via the high-speed interface 12 using the FW-writing FW.

Next, a processing operation of a firmware writing process executed by the firmware writing system 100 of this embodiment will be described. In this embodiment, the execution of the firmware writing process is started in a state where the FW-writing FW has been preliminarily written in the firmware region A2 of the NVM 14.

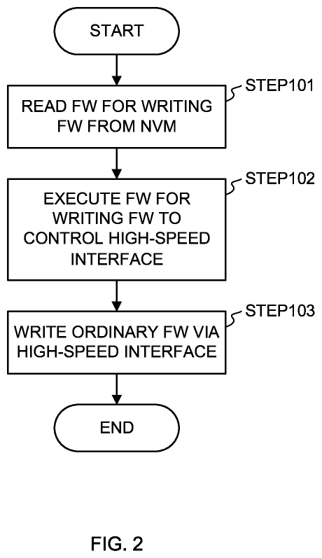

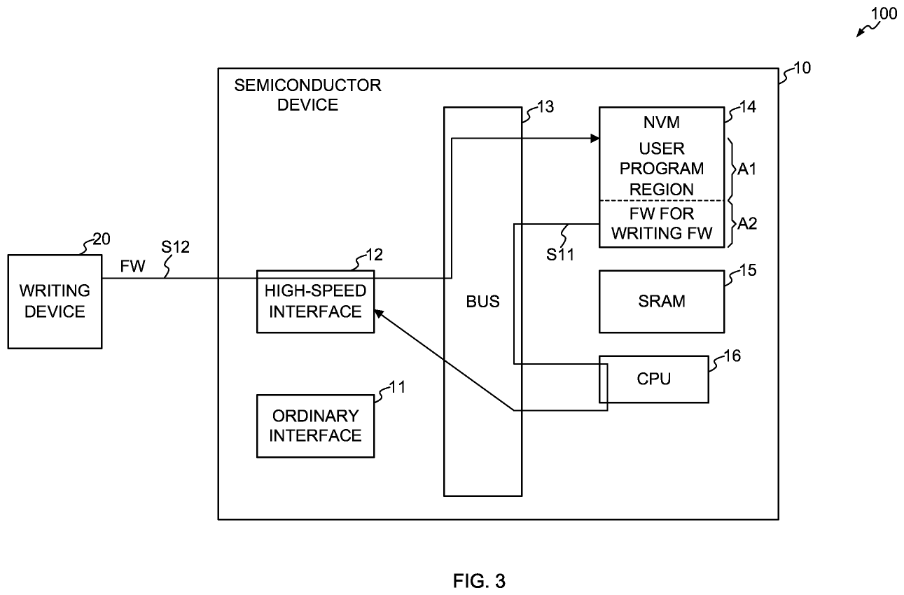

FIG. 2 is a flowchart illustrating a process routine of the firmware writing process of this embodiment. FIG. 3 is a diagram schematically illustrating the processing operation of the firmware writing process.

First, the CPU 16 reads the FW-writing FW stored in the firmware region A2 of the NVM 14 (STEP 101).

The CPU 16 executes the read FW-writing FW to run the high-speed interface 12 (STEP 102).

This results in performing the read of the FW-writing FW via the bus 13 and the control of the high-speed interface 12 based on the execution of the FW-writing FW as illustrated as “S11” in FIG. 3.

The high-speed interface 12 is supplied with the ordinary FW from the writing device 20 and transfers this to the user program region A1 of the NVM 14, and the ordinary FW is written (STEP 103).

This results in executing the write of the ordinary FW to the NVM 14 via the high-speed interface 12 and the internal bus 13 from the writing device 20 as illustrated as “S12” in FIG. 3.

As described above, the high-speed interface 12 is an interface that performs serial communication or parallel communication at a higher speed than the ordinary interface 11. Accordingly, by writing the ordinary FW via the high-speed interface 12, the writing process can be executed at high speed compared with a case where the ordinary FW is written via the ordinary interface 11.

In addition, the high-speed interface 12 is an interface that operates in response to the execution of the software for data transferring by the CPU 16. The high-speed interface 12 is extremely small in size compared with dedicated hardware that independently operates without requiring the execution of such software. Accordingly, for example, compared with a case where hardware dedicated to realizing a high-speed parallel write is disposed, an increase in circuit size can be reduced.

As described above, the firmware writing system 100 of this embodiment allows performing the firmware write at high speed while reducing the increase in circuit size.

### Embodiment 2

Next, Embodiment 2 of the present invention will be described. A firmware writing system of this embodiment has a configuration similar to that of the firmware writing system 100 of Embodiment 1, that is, the configuration of the block diagram illustrated in FIG. 1.

In the firmware writing system of this embodiment, the write of the FW-writing FW to the NVM 14 as a non-volatile memory has not been preliminarily performed at another timing, such as an inspection process, but is performed immediately before the write of the ordinary FW as a part of the firmware writing process. The firmware writing system of this embodiment is different from the firmware writing system 100 of Embodiment 1 in this respect.

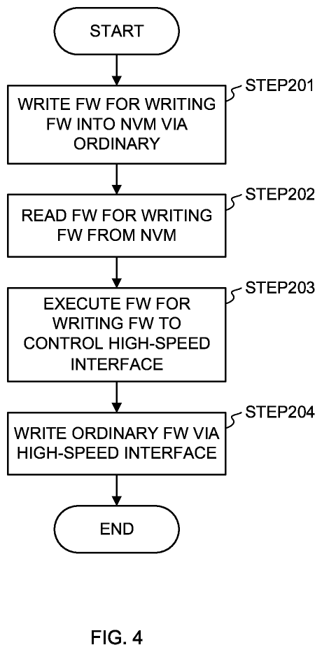

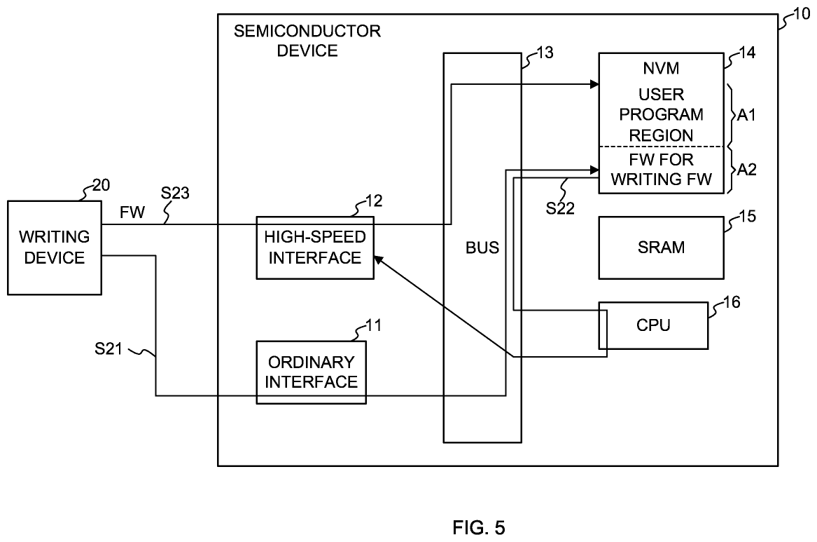

A processing operation of a firmware writing process executed by the firmware writing system of this embodiment will be described with reference to FIG. 4 and FIG. 5.

FIG. 4 is a flowchart illustrating a process routine of the firmware writing process of this embodiment. FIG. 5 is a diagram schematically illustrating the processing operation of the firmware writing process.

First, the writing device 20 writes the FW-writing FW into the firmware region A2 of the NVM 14 via the ordinary interface 11. That is, the writing device 20 supplies the FW-writing FW to the ordinary interface 11. The ordinary interface 11 transfers this to the firmware region A2 of the NVM 14 (STEP 201).

This results in performing the write of the FW-writing FW via the ordinary interface 11 and the bus 13 as illustrated as “S21” in FIG. 5.

The CPU 16 reads the FW-writing FW from the firmware region A2 of the NVM 14 (STEP 202).

The CPU 16 executes the read FW-writing FW to run the high-speed interface 12 (STEP 203).

This results in performing the read of the FW-writing FW via the bus 13 and the control of the high-speed interface 12 based on the execution of the FW-writing FW as illustrated as “S22” in FIG. 5.

The high-speed interface 12 is supplied with the ordinary FW from the writing device 20 and transfers this to the user program region A1 of the NVM 14, and the ordinary FW is written (STEP 204).

This results in executing the write of the ordinary FW to the NVM 14 via the high-speed interface 12 and the internal bus 13 from the writing device 20 as illustrated as “S23” in FIG. 5.

As described above, in the firmware writing system of this embodiment, the FW-writing FW is executed to run the high-speed interface 12, and the ordinary FW is written. Accordingly, similarly to Embodiment 1, a write period of the firmware (ordinary FW) can be shortened compared with a case where the ordinary FW is written via the ordinary interface 11.

As described above, the FW-writing FW is extremely small in size compared with the ordinary FW. In view of this, the write of the FW-writing FW performed using the ordinary interface 11 can be performed in a short period compared with a case where the write of the ordinary FW is performed using the ordinary interface 11. Accordingly, even considering a time period needed for the write of the FW-writing FW, the write period can be substantially shortened compared with a case where the ordinary FW itself is written via the ordinary interface 11.

Additionally, in the firmware writing system of this embodiment, the write of the FW-writing FW to the NVM 14 as a non-volatile memory is performed immediately before the write of the ordinary FW as a part of the firmware writing process.

Unlike this embodiment, when the write of the FW-writing FW to a non-volatile memory has been preliminarily performed at an occasion different from that for the write of the ordinary FW, data of the FW-writing FW may disappear by heat application depending on the non-volatile memory type. For example, in a manufacturing process of a semiconductor device, when heat is applied in mounting a chip on a substrate, the disappearance of the data of the FW-writing FW causes a problem in that the high-speed write of the ordinary FW cannot be performed.

In contrast to this, in the firmware writing system of this embodiment, since the write of the FW-writing FW is performed immediately before the write of the ordinary FW, such a problem does not occur. Moreover, when the FW-writing FW has been preliminarily written to the non-volatile memory, the memory area for the FW-writing FW is occupied until the write of the ordinary FW is performed. In contrast to this, with the firmware writing system of this embodiment, the memory area in the non-volatile memory can be widely utilized until the write of the ordinary FW is required. After the ordinary FW is written, the FW-writing FW may be erased every time if it is not required.

### Embodiment 3

Next, Embodiment 3 of the present invention will be described. A firmware writing system of this embodiment is different from the firmware writing system of Embodiment 2 in that the FW-writing FW is written into a volatile memory instead of a non-volatile memory.

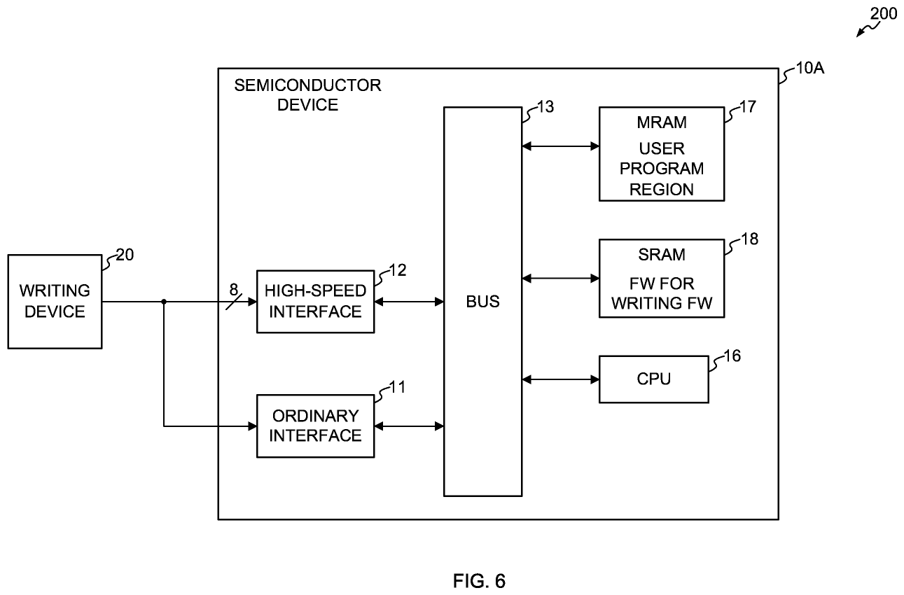

FIG. 6 is a block diagram illustrating a configuration of a firmware writing system 200 of Embodiment 3. A semiconductor device 10A of this embodiment has an MRAM 17 and an SRAM 18. The MRAM 17 and the SRAM 18 are examples of memory units of the semiconductor device 10A.

The Magnetoresistive Random Access Memory (MRAM) 17 is an example of a non-volatile memory built in the semiconductor device 10A. Unlike the NVM 14 of Embodiment 1, a firmware region for writing the FW-writing FW is not disposed in the MRAM 17.

The SRAM 18 is an example of a volatile memory built in the semiconductor device 10A. In this embodiment, the FW-writing FW is written into the SRAM 18.

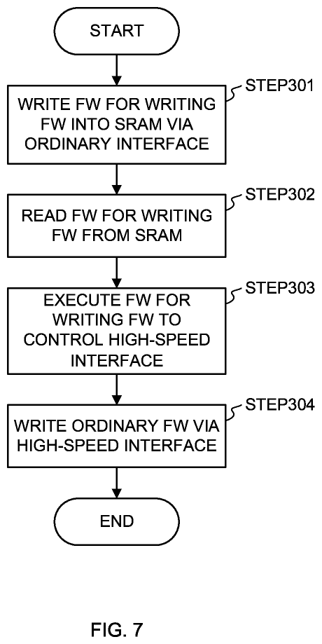

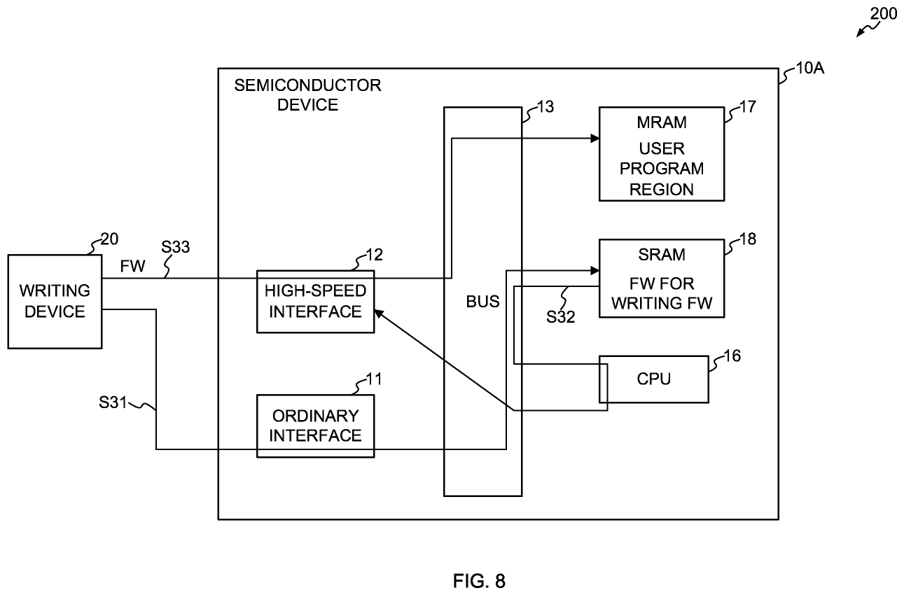

Next, a processing operation of a firmware writing process executed by the firmware writing system 200 of this embodiment will be described with reference to FIG. 7 and FIG. 8.

FIG. 7 is a flowchart illustrating a process routine of the firmware writing process of this embodiment. FIG. 8 is a diagram schematically illustrating the processing operation of the firmware writing process.

First, the writing device 20 writes the FW-writing FW into the SRAM 18 via the ordinary interface 11. That is, the writing device 20 supplies the FW-writing FW to the ordinary interface 11, and the ordinary interface 11 transfers this to the SRAM 18 (STEP 301).

This results in performing the write of the FW-writing FW via the ordinary interface 11 and the bus 13 as illustrated as “S31” in FIG. 8.

The CPU 16 reads the FW-writing FW from the SRAM 18 (STEP 302).

The CPU 16 executes the read FW-writing FW to run the high-speed interface 12 (STEP 303).

This results in performing the read of the FW-writing FW via the bus 13 and the control of the high-speed interface 12 based on the execution of the FW-writing FW as illustrated as “S32” in FIG. 8.

The high-speed interface 12 is supplied with the ordinary FW from the writing device 20 and transfers this to the MRAM 17, and the ordinary FW is written (STEP 304).

This results in executing the write of the ordinary FW to the MRAM 17 via the high-speed interface 12 and the internal bus 13 from the writing device 20 as illustrated as “S33” in FIG. 8.

As described above, in the firmware writing system 200 of this embodiment, the FW-writing FW is executed to run the high-speed interface 12, and the ordinary FW is written. Accordingly, similarly to Embodiment 1 and Embodiment 2, a write period of the firmware (ordinary FW) can be shortened.

Unlike the firmware writing systems of Embodiment 1 and Embodiment 2, in the firmware writing system 200 of this embodiment, the FW-writing FW is written into the volatile memory instead of the non-volatile memory. Accordingly, without occupying the memory area of the non-volatile memory, the write and the read of the FW-writing FW can be performed.

Unlike this embodiment, when the FW-writing FW is written into the non-volatile memory, an erasing work of the FW-writing FW is necessary to use the memory area for another usage after the writing process using the FW-writing FW is completed. However, in the firmware writing system 200 of this embodiment, since the FW-writing FW is written into the volatile memory, such erasing work is not necessary. In addition, since the volatile memory has a faster operating speed than the non-volatile memory, the write and the erasure of the FW-writing FW can be performed at high speed.

Note that the present invention is not limited to the embodiments described above. For example, in the above-described embodiments, a case where the high-speed interface 12 is constituted of the OSPI is described as an example. However, the configuration of the high-speed interface 12 is not limited to this, and the high-speed interface 12 may be constituted of, for example, a Quad Serial Peripheral Interface (QSPI), a Universal Serial Bus (USB), or the like.

Moreover, in the above-described embodiments, a case where the NVM and the MRAM are used as the non-volatile memory and the SRAM is used as the volatile memory is described as an example. However, the non-volatile memory and the volatile memory are not limited to them.

What is claimed is:

1. A semiconductor device comprising:
a processing control unit that executes a predetermined operation;
a memory unit;
an ordinary interface unit that transfers input data to the memory unit; and
a high-speed interface unit that operates by executing high-speed write firmware by the processing control unit to transfer input data to the memory unit at a higher speed than the ordinary interface unit.

2. The semiconductor device according to claim 1, wherein
the processing control unit writes ordinary firmware for executing the predetermined operation into the memory unit via the high-speed interface unit by executing the high-speed write firmware.

3. The semiconductor device according to claim 2, wherein
the memory unit has a non-volatile memory, and
the high-speed write firmware has been written in the non-volatile memory.

4. The semiconductor device according to claim 2, wherein
the memory unit has a non-volatile memory, and
the high-speed write firmware is written into the non-volatile memory via the ordinary interface unit.

5. The semiconductor device according to claim 2, wherein
the memory unit has a non-volatile memory and a volatile memory, and
the high-speed write firmware is written into the volatile memory via the ordinary interface unit.

6. The semiconductor device according to claim 3, wherein
the ordinary firmware is written into the non-volatile memory.

7. The semiconductor device according to claim 1, wherein
the ordinary interface unit is an interface that transfers data via one data line, and
the high-speed interface unit is an interface that transfers data via a plurality of data lines.

8. The semiconductor device according to claim 1, wherein
the ordinary interface unit is an interface that transfers data per data line at a first speed, and
the high-speed interface unit is an interface that transfers data per data line at a second speed faster than the first speed.

9. The semiconductor device according to claim 1, wherein
the ordinary interface unit is an interface for debugging.

10. A firmware writing method for writing ordinary firmware for executing a predetermined operation into a memory unit in a semiconductor device, wherein
the semiconductor device includes a processing control unit that executes the predetermined operation, the memory unit, an ordinary interface unit that transfers input data to the memory unit, and a high-speed interface unit that transfers input data to the memory unit at a higher speed than the ordinary interface unit, and
the firmware writing method comprises executing high-speed write firmware for controlling the high-speed interface unit by the processing control unit to write the ordinary firmware into the memory unit via the high-speed interface unit.

11. The firmware writing method according to claim 10, wherein
the firmware writing method includes inputting the high-speed write firmware from outside to write the high-speed write firmware into the memory unit via the ordinary interface unit.

12. The firmware writing method according to claim 11, wherein
the memory unit has a non-volatile memory, and
in the inputting, the high-speed write firmware is written into the non-volatile memory via the ordinary interface unit.

13. The firmware writing method according to claim 11, wherein
the memory unit has a non-volatile memory and a volatile memory, and
in the inputting, the high-speed write firmware is written into the volatile memory via the ordinary interface unit.

14. The firmware writing method according to claim 12, wherein
in the executing, the ordinary firmware is written into the non-volatile memory via the high-speed interface unit by executing the high-speed write firmware by the processing control unit.

15. The firmware writing method according to claim 10, wherein
the ordinary interface unit is an interface that transfers data via one data line, and
the high-speed interface unit is an interface that transfers data via a plurality of data lines.

16. The firmware writing method according to claim 10, wherein
the ordinary interface unit is an interface that transfers data per data line at a first speed, and
the high-speed interface unit is an interface that transfers data per data line at a second speed faster than the first speed.

17. The firmware writing method according to claim 10, wherein
the ordinary interface unit is an interface for debugging.

18. The firmware writing method according to claim 10, wherein
the semiconductor device is built in an embedded device to control an operation of a device including the embedded device.

19. A firmware writing system comprising:
a semiconductor device including a processing control unit that executes a predetermined operation, a memory unit, an ordinary interface unit that transfers input data to the memory unit, and a high-speed interface unit that transfers input data to the memory unit at a higher speed than the ordinary interface unit; and
a writing device, wherein
high-speed write firmware for controlling the high-speed interface unit is written into the memory unit,
the writing device supplies ordinary firmware for executing the predetermined operation to the high-speed interface unit, and
the processing control unit writes the ordinary firmware into the memory unit via the high-speed interface unit by reading the high-speed write firmware from the memory unit and executing the high-speed write firmware.

20. The firmware writing system according to claim 19, wherein
the writing device supplies the high-speed write firmware to the ordinary interface unit, and
the ordinary interface unit transfers the high-speed write firmware to the memory unit.
